(19) United States
(12) Patent Application Publication
(10) Pub. No.: US 2005/0047243 A1
(43) Pub. Date: Mar. 3, 2005

(54) Media sensing via digital image processing

(76) Inventor: Chee Chong Hin, Penang (MY)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/652,287

(22) Filed: Aug. 29, 2003

(51) Int. Cl. G11C 7/00

(52) U.S. Cl. 365/222

(57) ABSTRACT

What is disclosed is a method, device, and system for the automated determination of output media characteristics, and for the further automatic adjustment of an application to most efficiently use the determined output media type.

### TECHNICAL FIELD

The present invention relates to the field of output media characterization, and the automatic adjustment of associated applications.

### BACKGROUND OF THE INVENTION

Specific applications are designed to translate data to output media. Because the specific requirements of these applications differ widely, a variety of output media classes are available to suit the specifics of a desired application. For any particular output media class, there may also be a variety of different output media types. For example, computers use a printer application to translate electronic data to an output media. The typical printer application, uses the output media class of print media. The class of print media, however, contains numerous different print media types: paper, transparencies, or other materials available as smooth or glossy, thick or thin, having various sizes, and other characteristics.

Each different media type of a media class can require different techniques for the effective and efficient translation of data to that media type. When an application has the ability to translate data to multiple media types in a media class, the functions of the application must often be changed in order to efficiently and effectively translate the data. Typically, it is up to the user to determine the type of output media in use, and to adjust the application's functions accordingly.

### BRIEF SUMMARY OF THE INVENTION

Described herein is a method for determining characteristics of output media by capturing an image of a surface of an output medium, and determining characteristics of the output medium from the image. The various embodiments also include a device that determines characteristics of output media by capturing an image of a surface of an output medium, and determining characteristics of the output media from the captured image. The embodiments further include a system for determining characteristics of an output media having a sensor for capturing an image of a surface of an output medium, and logic to determine characteristics of the output medium from the captured image.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawing, in which:

FIG. 1A is an example printing system;

FIG. 1B in an example arrangement of one aspect of an embodiment of the present invention;

FIG. 2 is an example image matrix in accordance with an aspect of one embodiment of the present invention;

FIG. 3 is an example of a filter kernel in accordance with one aspect of an embodiment of the present invention;

FIG. 4 is an example of a resultant matrix in accordance with one aspect of an embodiment of the present invention;

FIG. 5 is an example of an image in accordance with one aspect of an embodiment of the present invention;

FIG. 6 is an example of an image in accordance with one aspect of an embodiment of the present invention;

FIG. 7 is an example of an image matrix in accordance with one aspect of an embodiment of the present invention;

FIG. 8 is an example of an image matrix in accordance with one aspect of an embodiment of the present invention; and

FIG. 9 is an example of a computer system adapted in accordance with one aspect of an embodiment of the present invention.

FIG. 10 is a flow diagram in accordance with one embodiment of the present invention.

### DETAILED DESCRIPTION OF THE INVENTION

Applications using output media often have improved performance when their functions are adjusted to suit the specific characteristics of the media type in use. However, current applications typically require the user to determine the characteristics of the output media type, and then manually adjust the application's functions accordingly. The method, system, and device described herein relates to automatically determining the characteristics of the output media type used by an application and then automatically changing the application's functions to best suit the output media type in use. One use is in the determination and characterization of the different types in the output media class of print media, and in the automatic adjustment of the printer application, but uses in fax machines, copy machines, and other like applications can easily be adapted.

Modern printers have the capability of printing on a large number of print media types, but characteristics of print media types, and the appropriate associated printer functions, can vary widely. For example, thicker heavier papers may require more ink and a higher number of passes from the printer head to ensure successful printing than lighter draft-weight papers. For peak performance, the appropriate printer functions should be matched with the characteristics of the print media type. Current printers require the user to determine the type of print media in use, and then manually change the appropriate printer functions so that the printer can effectively print to that print media type. One embodiment of the present invention may be used in a conventional printer to automatically determine the characteristics of the print media type used in a printer for a given print media. This embodiment may select and control the appropriate printer functions for effective printing to the determined print media type.

To facilitate understanding, this description uses the example of determining the characteristics of output media types in the class of print media, and then automatically selecting the appropriate printer function control. It will be appreciated by those of ordinary skill in the art that the present invention is not limited to any specific types of print media. For example, it will be apparent to one skilled in the art that embodiments could be used to determine the characteristics of draft paper, bond paper, stock paper, rough paper, smooth paper, glossy paper, or any other type of paper media whose characteristics may be determined from captured images. Further, it will be apparent to those of ordinary skill in the art that the embodiments are not limited to paper media, but may be used with similar non-paper print media, such as transparencies, labels, plastic stocks, substrates for specialty printing such as PVC, polyester or polycarbonate, or any other media type associated with the class of print media.

It will also be appreciated by those of ordinary skill in the art that embodiments of the present invention can be used with all media classes. Although the example of print media is used, other embodiments include but are not limited to, printing on three dimensional objects, printing type construction of two and three dimensional objects, data output on to the surface of retail products such as bottles or cans, output on films or negatives, etching onto electrical substrates, or any other output media classes known or later developed whose characteristics may be determined through image capture. Further, the embodiments may be used on output media classes not visually discernable by the user, including but not limited to computer readable storage media and sound media, but whose characteristics may be determined through image capture.

It will be further appreciated that embodiments of the present invention may be used with applications for converting data to any output media class, and for all applications in any specific class. For example, in the class of print media, embodiments of the present invention are applicable to inkjet, bubble jet, impact, laser, or any other printer type now known or later developed. It will be thus appreciated that embodiments of the present invention may be used in any application where the determination of output media characteristics and/or related application function selection is useful.

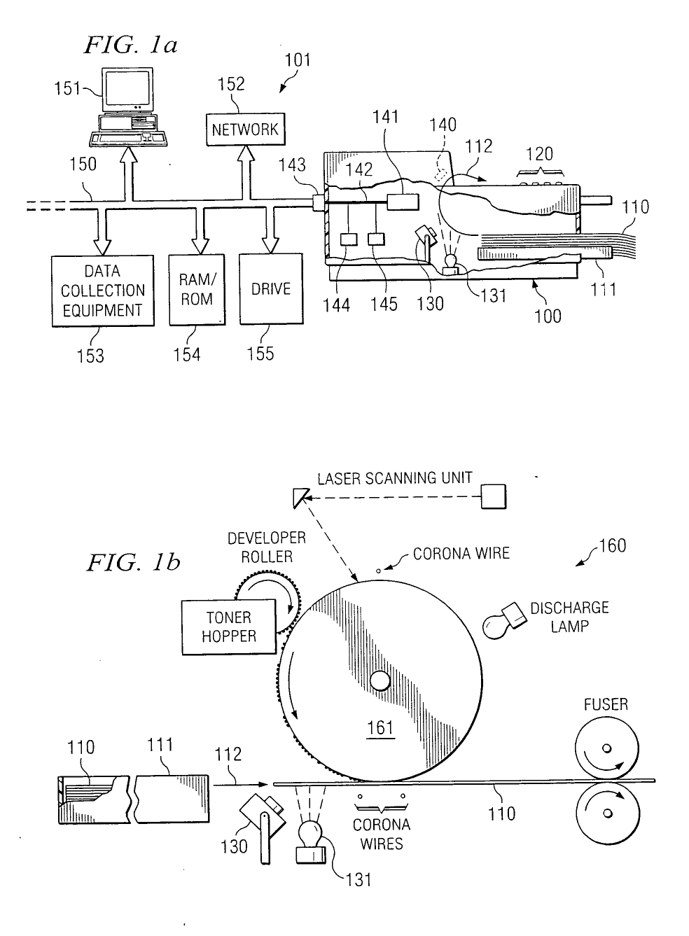

FIG. 1A depicts an example printing system 101 in a highly generalized form, and is included to provide a context for describing certain aspects of one embodiment of the present invention. It will be appreciated by those of ordinary skill in the art that some printing processes may deviate significantly from those depicted, but that the generalized description is a suitable context for an embodiment of the present invention and in no way limits its scope.

In FIG. 1A, printer 100 translates data onto print medium 110. Printer processing unit 141, a central processing unit suitable for use in printers, is connected to a printer bus 142. Preferably, printer 100 has random access memory (RAM) 144, which may be SRAM, DRAM, SDRAM, or the like. Printer 100 preferably includes read-only memory (ROM) 145 which may be PROM, EPROM, EEPROM, or the like. RAM 144 and ROM 145 hold user data and system data, and programs, as is well known in the art. For example, RAM 144 may be used to buffer data received from computer 151 for printing to print media 110.

Printer 100 preferably has interface adapter 143 which may allow other devices to interact with printer 100. The data used by printer 100 preferably flows through data transmission bus 150. Data transmission bus 150 preferably connects printer 100 to the various means of collecting, producing, computing, or otherwise creating or holding data for printing. These means may include, but are not limited to, the means depicted in FIG. 1A. By way of example, computer system 151 may relay electronic data to printer 100 through data transmission bus 150. Computer system 151 may be a personal computer, mainframe computer, laptop computer, computer workstation, multi-processor server, handheld computer, or any other computing device which may have data suitable for printing. Network 152 may be an ETHERNET, intranet, extranet, wireless connection, or any other multi-user connection used to send electronic data from a plurality of sources to printer 100 through data transmission bus 150. Printer 100 may be tasked to the conversion of data collected by a sensor or other measuring apparatus 153. Printer 100 may also convert data directly from a user through a drive apparatus 155 which may be, but is not limited to, a compact disc (CD) drive, floppy disk drive, or tape drive. Conversely, the data converted by printer 100 may come directly from memory sources 154 such as, but not limited to, RAM, ROM, hard drives, or other memory storage device.

Printer 100 is used to produce printed versions of data and may be any one of a plurality of printer design types including, but not limited to, dot matrix or other impact printers, inkjet or other similar designs, or laser or other similar designs. FIGS. 1A and 1B depict alternate possible arrangements of certain aspects of one embodiment of the present invention. It will be appreciated by those skilled in the art that the present invention is not limited to the arrangements depicted, but rather embodiments may be fitted to other printer types, such as drawer feed or stack feed printers, without undue experimentation.

The cutaway portion of FIG. 1A depicts a generalized arrangement that can illustrate, for example, both impact printer and inkjet type printer designs. In FIG. 1A, print medium 110 is typically held in a media tray 111 for use by printer 100. Printer 100 draws print medium 110 along print media path 112 such that print medium 110 passes proximate to printer head 140. Information is converted by printer 100 and transferred to print medium 110 by printer head 140 through any of the numerous methods well known in the art.

FIG. 1A further shows that, according to one aspect of an embodiment, printer 100 includes a print media sensor 130 and, preferably, a light source 131 attached adjacent to print media path 112 interposed between media tray 111 and printer head 140. Media sensor 130 can be any sensor or device capable of capturing an image of a surface of print media 110 as it moves along print media path 112. FIG. 1B depicts a generalized laser printer. Instead of the print head 140 as shown in FIG. 1A, a laser printing system 160 typically utilizes a photoreceptor drum 161. In one aspect of an embodiment of the present invention, sensor 130, and light source 131, are arranged adjacent to print media path 112 interposed between media tray 111 and photoreceptor drum 161. In the above described embodiments, an image of an output medium's surface is taken as it travels along a print media path. Those of ordinary skill in the art will appreciate that the embodiments are not limited to the example arrangements, but may capture images in a manner most convenient to a particular print application (as print medium 110 lays in media tray 111, for example).

Embodiments of the present invention utilize images of a surface of an output medium. These images are captured by a sensor and associated circuitry. An example sensor may be a photo array such as the type currently used in the Optical Navigation Technology (ONT) disclosed in U.S. Pat. No. 5,089,712, or in optical computer mice manufactured by Microsoft, Inc. and Logitech, Inc. It will be appreciated by one of ordinary skill in the art that the embodiments are not limited to the sensors described above, and that any sensor now known or later developed capable of capturing an image of a surface of a print media may be in the embodiments of the present invention. It will be further appreciated by those skilled in the art that there are numerous methods of assisting sensor 130 in capturing a suitable image of the surface of a print medium. For example, one aspect of an embodiment of the present invention uses a light source 131 (FIGS. 1A and 1B), such as a light emitting diode, to shine light on the print media at an acute angle in order to exaggerate the topography of print medium 110. The shadows produced can facilitate the calculations made below. It will be appreciated by one of ordinary skill in the art that any method of assisting sensor 130 in capturing the topographical features of print medium 110 may be included in embodiments of the present invention.

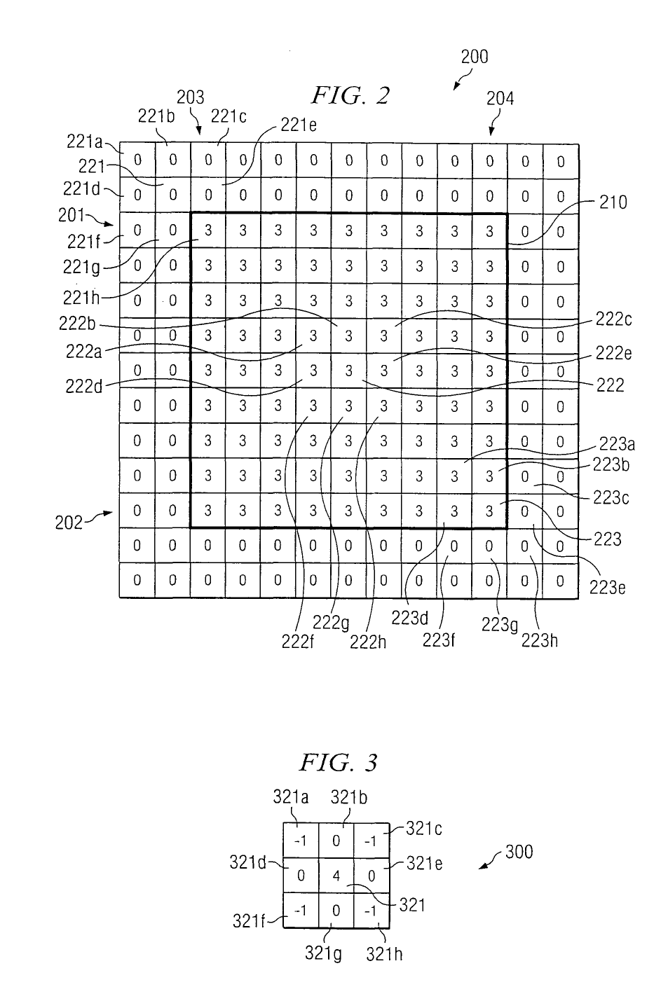

Embodiments of the present invention can determine the characteristics of the output media type being used from the captured image. The image captured by sensor 130 can be converted into a form suitable to the various embodiments. In one aspect of an embodiment of the present invention, the image captured by sensor 130 is converted into a two dimensional matrix 200, like that shown in FIG. 2. Matrix 200 may be comprised of elements, such as elements 221, 222, and 223, that have values corresponding to the intensity of light at an associated portion of the image. The light intensity of a surface's image will vary with the changing topography of that surface, so it is possible to capture the topographical changes of a surface by marking the change in image light intensity. For the present example, print medium 110 was given a raised square on its surface, thus this topographical feature should be represented in the image. FIG. 2 is a matrix 200 corresponding to this surface and topographical feature. The topographical feature is represented by square 210, which contains non-zero valued elements bordered by matrix rows 201 and 202 and matrix columns 203 and 204.

One aspect of one embodiment of the present invention enhances the variations in element values by using digital signal processing (DSP) image filters, a class of filters called DC Removal filters for example, as a filtering means for enhancing the topographical features captured by sensor 130. Such filters commonly use a mathematical process to minimize the effect of uniform portions in the captured image. DC Removal (DCR or “High Pass”) filters remove the low frequency spatial content of a digital image. Using such a “High Pass” filter enhances the “roughness” of an image by emphasizing the edges of a topographical feature, while simultaneously minimizing the “plateaus” and “valley floors” of topographical features typically characterized by regions of matrix 200 with similar, or uniform, element values. It will be apparent to one of ordinary skill in the art that although “High Pass” filters are used here by example, the embodiments of the present invention are not limited to the use of these filters.

In one aspect of an embodiment of the present invention, each element in matrix 200 has a number of associated elements. Element 221, for example, might have associated elements 221a, 221b, 221c, 221d, 221e, 221f, 221g, and 221h. The image captured by the photo array of a perfectly smooth surface containing no topographical features would correspond to a matrix of numbers very close in value. When a filter such as a DC removal filter operates on the elements of such an image, it compares each element value with the value of its neighbors. If the neighboring pixels are the same value, it turns that pixel to zero. In a like manner, the filter steps through the pixels comparing each selected pixel to its nearest neighbors.

For one aspect of an embodiment of the present invention, FIG. 3 represents an example kernel 300 of a “High Pass” filter. This nine element matrix contains a center element 321 and eight associated elements 321a, 321b, 321c, 321d, 321e, 321f, 321g, and 321h. An example “High Pass” filter might apply kernel 300 to each of the elements of matrix 200 to enhance the edges of topographical features represented in matrix 200. For example, the “High Pass” filter might apply kernel 300 to matrix element 221 by multiplying element 221, and its associated elements 221a through 221h, with a corresponding kernel element in the following manner:

TABLE 1

| Matrix Elements | Resultant Value |
|---|---|
| 221 × 321 = 0 × 4 = | 0 |
| 221a × 321a = 0 × −1 = | 0 |
| 221b × 321b = 0 × 0 = | 0 |
| 221c × 321c = 0 × −1 = | 0 |
| 221d × 321d = 0 × 0 = | 0 |
| 221e × 321e = 0 × 0 = | 0 |
| 221f × 321f = 0 × −1 = | 0 |
| 221g × 321g = 0 × 0 = | 0 |
| 221h × 321h = 3 × −1 = | −3 |

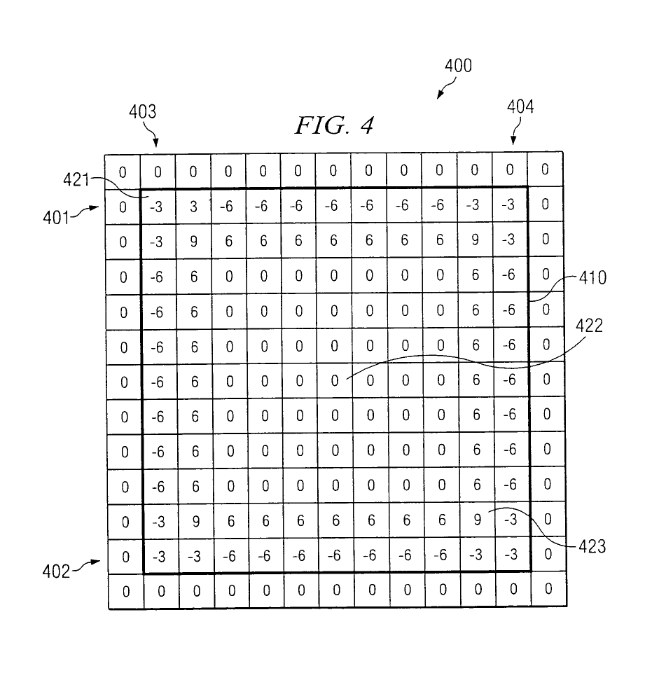

This application of the kernel to the matrix 200 produces a value of −3 for element 421, of resultant matrix 400 in FIG. 4, by adding the results of the above table in the following manner:

TABLE 2

| Matrix Elements | Resultant Value |
|---|---|
| 221 × 321 = 0 × 4 = | 0 |
| | + |
| 221a × 321a = 0 × −1 = | 0 |
| | + |
| 221b × 321b = 0 × 0 = | 0 |
| | + |
| 221c × 321c = 0 × −1 = | 0 |
| | + |
| 221d × 321d = 0 × 0 = | 0 |
| | + |
| 221e × 321e = 0 × 0 = | 0 |
| | + |
| 221f × 321f = 0 × −1 = | 0 |
| | + |
| 221g × 321g = 0 × 0 = | 0 |
| | + |
| 221h × 321h = 3 × −1 = | −3 |
| Element 421 = | −3 |

By following the same method, element 223 and its associated elements 223a, 22b, 223c, 223d, 223e, 223f, 223g, and 223h produce a value of (9) for element 423 of resultant matrix 400, in FIG. 4, when kernel matrix 300 operates on element 223. This illustrates how a “High Pass” filter enhances the edges of an image's topographical features. The formulas utilized are as follows:

TABLE 3

| Matrix elements | Resultant Value |
|---|---|
| 223 × 323 = 3 × 4 = | 12 |
| | + |
| 223a × 323a = 3 × −1 = | −3 |
| | + |
| 223b × 323b = 3 × 0 = | 0 |
| | + |
| 223c × 323c = 0 × −1 = | 0 |
| | + |
| 223d × 323d = 3 × 0 = | 0 |
| | + |
| 223e × 323e = 0 × 0 = | 0 |
| | + |
| 223f × 323f = 0 × −1 = | 0 |
| | + |
| 223g × 323g = 0 × 0 = | 0 |
| | + |
| 223h × 323h = 0 × −1 = | 0 |
| Element 423 = | 9 |

By following the same method, element 222 and its associated elements 222a, 22b, 222c, 222d, 222e, 222f, 222g, and 222h produce a new value of zero when kernel matrix 300 operates on element 222. The new value of zero is the result of element 223 being surrounded by elements of identical value, illustrating how a “High Pass” filter eliminates matrix 200 regions with similar element values (“plateaus” and “valley floors”). The formulas utilized are as follows:

TABLE 4

| Matrix Elements | Resultant Value |
|---|---|
| 222 × 322 = 3 × 4 = | 12 |
| | + |
| 222a × 322a = 3 × −1 = | −3 |
| | + |
| 222b × 322b = 3 × 0 = | 0 |
| | + |
| 222c × 322c = 3 × −1 = | −3 |
| | + |
| 222d × 322d = 3 × 0 = | 0 |
| | + |
| 222e × 322e = 3 × 0 = | 0 |
| | + |
| 222f × 322f = 3 × −1 = | −3 |
| | + |
| 222g × 322g = 3 × 0 = | 0 |
| | + |
| 222h × 322h = 3 × −1 = | −3 |
| Element 422 = | 0 |

Resulting matrix 400 of FIG. 4 is an example result of having kernel matrix 300 operate on each element of image matrix 200. The square 210, representing a topographical feature of surface image matrix 200 in FIG. 2, is replaced by a hollow square 410 bordered by resulting matrix rows 401 and 402 and resulting matrix columns 403 and 404. The edges of square 210 have been exaggerated, while all regions of similar element values have resulted in zero (0) resultant values. Thus, it is the changes in print medium 110's topography that are retained. A print media characterized by many topographical features like square 210 of FIG. 2, would have a resultant matrix with numerous exaggerated edges like hollow square 410 in FIG. 4. In contrast, a print medium 110 characterized by comparatively few topographical features and large regions of similar element values would have few exaggerated edges in its resultant matrix like those of hollow square 410.

With the edges of print medium 110's topographical features emphasized, the number of resultant matrix 400 elements with non-zero values could be used by one aspect of an embodiment of the present invention to measure print medium 110's characteristics. For a particular resulting matrix, a large number of non-zero values would correspond to a print medium with a large number of topographical edges. In contrast, a resulting matrix of zero values would correspond to a print medium with no topographical features. One aspect of an embodiment of the present invention could then count the number of elements of the resulting matrix with a value above some threshold value. For example, if the threshold value were “3,” the resulting matrix 400 would have 32 elements with values in excess of this value. Embodiments of the present invention could associate this number “32” with certain characteristics (such as “roughness”) and determine the output media type being used or determine the characteristics of a print medium directly from the threshold value using any appropriate method, such as accessing a database.

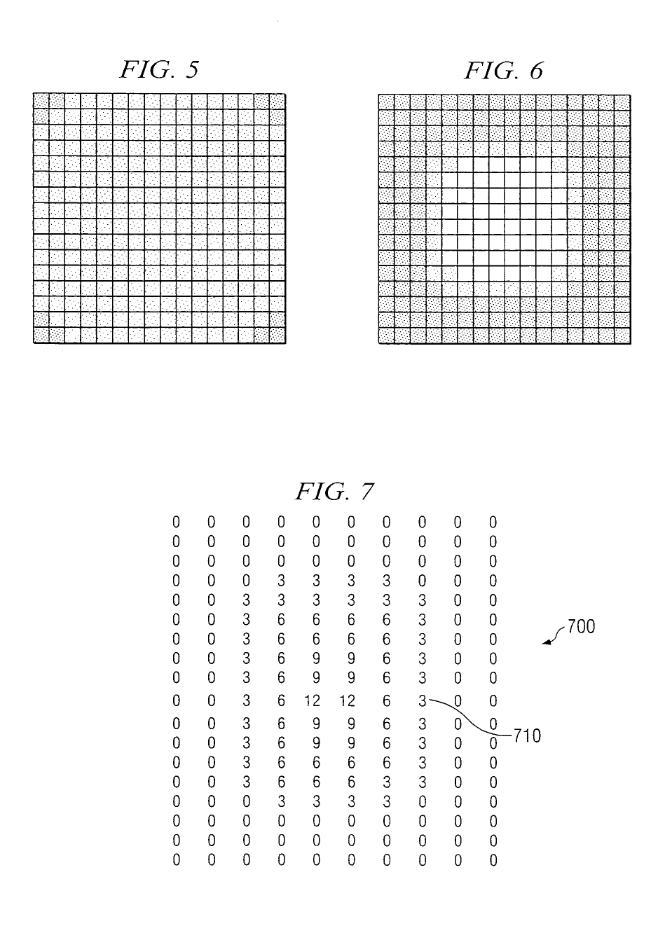

One aspect of an alternative embodiment of the present invention might use the average light intensity in a captured image to determine print media characteristics. Print media surface characteristics effect the images taken of the surface. For example, a “glossy” or smooth surface can produce an image with an intense white spot near the center of the image. In comparison to this bright spot, the portions of the image in the background will be far less intense. The image of a rough or more uneven print media surface will not evidence a region of high light intensity against a darker background, but rather result in an image with a large number of more moderately contrasting light and dark areas. This effect may be produced by arranging light source 131 of FIGS. 1B and 1C to direct light at angles approaching the perpendicular to the surface of the output media. Examples of the differing types of images are displayed in FIGS. 5 and 6. FIG. 5 is an example image of a “rough” or uneven print media surface. That results in an image with varying areas of moderate light intensity. Image 600 is an example image of a glossy surface of a smooth print medium that produces an image with a region of high light intensity, on a background of lower intensity.

Through one aspect of this embodiment of the present invention, images 500 and image 600 are preferably converted into two-dimensional matrices of elements having values corresponding to the light intensity of the image. In FIG. 7, matrix 700, corresponding to the image of FIG. 6, consists of individual elements such as element 710, with values corresponding to the intensity of light at the associated portion of the image. In FIG. 8, matrix 800, corresponding to the image of FIG. 5, can comprise of individual elements such as element 810 also having values corresponding to the intensity of light at the associated portion of the images.

A print media's surface characteristics can be found by determining the respective image's specularity. For each matrix, the peak intensity value is divided by the average intensity value for the entire matrix. This value, called the specularity, can then be used to determine the print media surface characteristics. A glossy surface results in a high peak matix 800 element value. When divided by the average matrix 800 element value, held low by the darker background, the image of a glossy surface results in a high specularity. A rougher surface does not display an area of disproportionally high matrix element values, and the peak intensity will be closer in value to the average pixel intensity. This results in a specularity that is lower. An embodiment of the present invention may then associate the determined specularity with known characteristics, such as “rough” or “smooth”, or with a print media type using any appropriate method, such as accessing a database.

It will be appreciated by one of ordinary skill in the art that the embodiments of the present invention are not limited to the methods of determination used here by way of example. It will also be appreciated that the embodiments of the present invention may include any method that utilizes variations in a captured image's light intensity to determine the characteristics of a used output media.

A further aspect of the various embodiments of the present invention could use the determined characteristics of the print media type in use, to adjust the appropriate functions of the application. In the example of a computer printer, an embodiment may determine that a rough paper requires more ink, and adjust the printer functions to compensate. It will be appreciated by those of ordinary skill in the art that the embodiments of the present invention are not limited to printer applications. It will be further appreciated that the embodiments of the present invention may be applicable to all output media applications.

The various embodiments of the present invention might use computer-based logic to calculate the values used, to determine media characteristics, to adjust the application functions, or any other aspect. When implemented via computer-executable instructions, various aspects of the embodiments of the present invention are in essence the software code defining the operations of such various elements. The executable instructions or software code may be obtained from a readable medium (e.g., a hard drive media, optical media, EPROM, EEPROM, tape media, cartridge media, flash memory, ROM, memory stick, and/or the like) or communicated via a data signal from a communication medium (e.g., the Internet). In fact, readable media can include any medium that can store or transfer information.

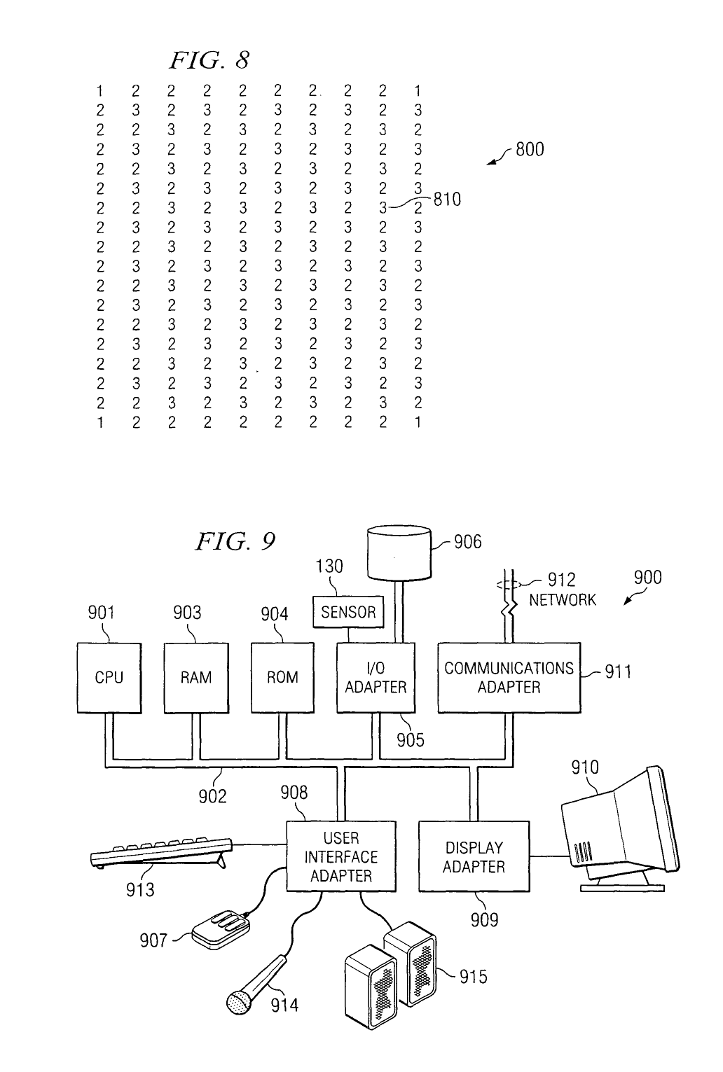

FIG. 9 illustrates an example computer system 900 adapted according to embodiments of the present invention. That is, computer system 900 comprises an example system on which embodiments of the present invention may be implemented. Central processing unit (CPU) 901 is coupled to system bus 902. CPU 901 may be any general purpose CPU. Suitable processors include without limitation any processor from HEWLETT-PACKARD's ITANIUM family of processors, HEWLETT-PACKARD's PA-8500 processor, or INTEL's PENTIUM® 4 processor. However, the present invention is not restricted by the architecture of CPU 901 as long as CPU 901 supports the inventive operations as described herein. CPU 901 may execute the various logical instructions according to embodiments of the present invention.

Computer system 900 also preferably includes random access memory (RAM) 903, which may be SRAM, DRAM, SDRAM, or the like. Computer system 900 preferably includes read-only memory (ROM) 904 which may be PROM, EPROM, EEPROM, or the like. RAM 903 and ROM 904 hold user and system data and programs, as is well known in the art.

Computer system 900 also preferably includes input/output (I/O) adapter 905, communications adapter 911, user interface adapter 908, and display adapter 909. I/O adapter 905, user interface adapter 908, and/or communications adapter 911 may, in certain embodiments, enable a user to interact with computer system 900 in order to input information, such as data relating to the assignment of media characteristics to the values calculated by the methods above.

I/O adapter 905 preferably connects to storage device(s) 906, such as one or more of hard drive, compact disc (CD) drive, floppy disk drive, tape drive, etc. to computer system 900. The storage devices may be utilized when RAM 903 is insufficient for the memory requirements associated with storing data for media characterization tables. I/O adapter 905 also preferably connects to sensor 130 of FIG. 1. Through sensor 130, computer system 900 receives the information necessary to determine the characteristics of the subject media. Communications adapter 911 is preferably adapted to couple computer system 900 to network 912. User interface adapter 908 couples user input devices, such as keyboard 913, pointing device 907, and microphone 914 and/or output devices, such as speaker(s) 915 to computer system 900. Display adapter 909 is driven by CPU 901 to control the display on display device 910 to, for example, display the user interface of embodiments of the present invention.

It shall be appreciated that the present invention is not limited to the architecture of system 900. For example, any suitable processor-based device may be utilized, including without limitation personal computers, laptop computers, computer workstations, and multi-processor servers. Moreover, embodiments of the present invention may be implemented on application specific integrated circuits (ASICs) or very large scale integrated (VLSI) circuits. In fact, persons of ordinary skill in the art may utilize any number of suitable structures capable of executing logical operations according to the embodiments of the present invention. The aspects of the present invention might, in whole or in part, be included in the systems of printer 100 of FIGS. 1A, 1B, and 1C described above. It will be appreciated by one skilled in the art, that the embodiments of the present invention are not limited to system 900 or the system described in FIG. 1, and that the embodiments of the present invention may be implemented on any number of suitable systems.

Further possible embodiments of the present invention include logic to alter the functionality of the application utilizing the methods disclosed herein. Again turning to the example of the computer printer, one possible embodiment of the present invention uses the calculations described above, computes the media characteristics using a system such as the system of FIG. 9, and alters the functions of the printer such that the printer most effectively use the print media.

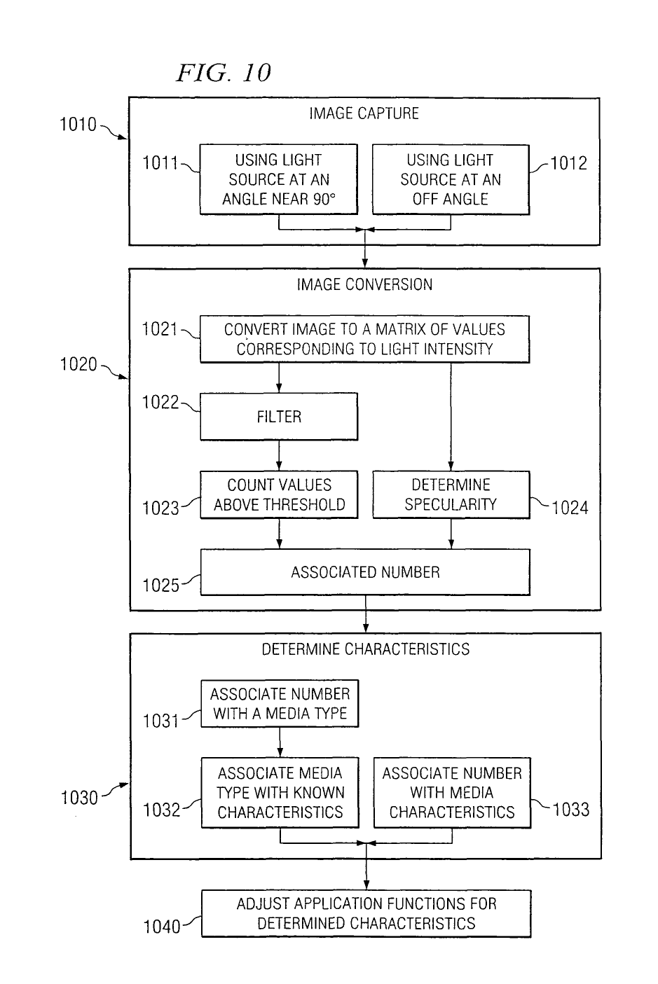

FIG. 10 depicts an example flow chart for some embodiments of the present invention described herein. Embodiments of the present invention capture an image of the print media in a capture image step 1010. This step might be done with a light source (131 of FIGS. 1A and 1B) placed at an angle close to 90° in substep 1011 or at an off angle in substep 1012.

Step 1020 converts the image captured. As described herein for the different embodiments, the embodiments may use logic to convert the image to a matrix of values in substep 1021. In some embodiments, the matrix may use logic to filter in substep 1022 and the number of resulting values above a threshold value are counted in substep 1023. Other embodiments may use logic to determine the specularity in substep 1024. Both embodiment types result in a number associated with the print media in substep 1025.

In Step 1030, embodiments of the present invention may use logic to determine the characteristics of the print media in use. Some embodiments use logic to perform substep 1031 associating the determined number with a media type, and substep 1032 associating the media type with known characteristics. Other embodiments use logic to perform substep 1033 which correlates media characteristics with the determined number. In step 1040, the embodiments may then use a mechanism, logic, or other means to adjust the application to the determined characteristics of the print media in use.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method for determining characteristics of output media, comprising:
capturing an image of a surface of an output medium;
converting said image into an array of elements having values that correspond to light intensity; and
determining characteristics of said output medium from differences between said values of said elements.

2. The method of claim 1 wherein said determining comprises:
identifying a number of said elements with a said value above a threshold value; and
associating said number with known characteristics of output media.

3. The method of claim 1 further comprising:
operating on said image to enhance said differences in said values of said elements.

4. The method of claim 1 further comprising:
determining what aspects of an application correspond to said characteristics of said output medium; and
adjusting said aspects of said application to correspond to said characteristics of said output medium.

5. The method of claim 4 wherein said application is a printer and said output medium is print media.

6. The method of claim 1 where said surface is illuminated by a light source.

7. The method of claim 1 further comprising:
determining the specularity of said image; and
associating said specularity with known characteristics of a type of said output medium.

8. A device for determining characteristics of output media comprising:
means for capturing an image of a surface of an output medium;
means for converting said image to an array of elements with values corresponding to light intensity; and
means for using differences in said values of said elements to determine characteristics of said output medium.

9. The device of claim 8 further comprising:
means for identifying a number of said elements with a said value above a threshold value; and
means of associating said number with known characteristics of output medium type.

10. The device of claim 8 further comprising:
means for operating on said array of said elements to enhance said differences in said values.

11. The device of claim 8 further comprising:
means for determining what aspects of an application correspond to said characteristics of said output medium; and
means for adjusting said aspects of said application to correspond to said characteristics of said output medium.

12. The device of claim 11 wherein the said application is a printer and the said output medium is print media.

13. The device of claim 8 wherein said surface is illuminated by a light source.

14. The device of claim 8 further comprising:
means of obtaining the specularity of said image; and
means for determining said characteristics from said specularity.

15. A system for determining characteristics of output media comprising:
a sensor for capturing an image of a surface of an output medium;
converting logic to convert said image to an array of elements with values corresponding to light intensity; and
determining logic to determine characteristics of said output medium from the differences in said values.

16. The system of claim 15 further comprising:
identifying logic to identify a number of said elements with a said value above a threshold value; and
associating logic to associate said number with known characteristics of output media.

17. The system of claim 15 further comprising:
filtering logic to operate on said array of said elements to enhance said differences of said values.

18. The system of claim 15 further comprising:
correlating logic to determine what aspects of an application correspond to said characteristics of said output medium; and
a mechanism to adjust said aspects of said application to correspond to said characteristics of said output medium.

19. The system of claim 18 wherein the said application is a printer and the said output medium is print media.

20. The system of claim 15 further comprising:
identifying logic to obtain the specularity of said image; and
determining logic to determine said characteristics from said specularity.
